(19) United States
(12) Patent Application Publication
(10) Pub. No.: US 2009/0230519 A1
(43) Pub. Date: Sep. 17, 2009

(54) Semiconductor Device

(75) Inventors: Ralf OTREMBA, Kaufbeuren (DE); Wei Kee CHAN, Kuala Lumpur (MY); Stanley JOB DORAISAMY, Kuala Lumpur (MY); Stefan KRAMP, Villach (AT); Fong LIM, Ayer Keroh (MY); Xaver SCHLOEGEL, Sachsenkam (DE)

Correspondence Address: INFINEON TECHNOLOGIES AG;Patent Department, MUC 11.1.507, P.O. Box 221644, Munich, 80506, DE

(73) Assignee: INFINEON TECHNOLOGIES AG, Neubiberg (DE)

(21) Appl. No.: 12/048,234

(22) Filed: Mar. 14, 2008

(51) Int. Cl. H01L 23/495; H01L 21/60

(52) U.S. Cl. 257/666; 438/123; 257/E23.031; 257/E21.502

(57) ABSTRACT

This application relates to a semiconductor device comprising: a carrier comprising a chip island and at least one first external contact element; only one semiconductor chip, wherein the semiconductor chip comprises a first electrode on a first surface and a second electrode on a second surface opposite to the first surface and wherein the first electrode is attached to the chip island; and a metal structure comprising a plate region attached to the second electrode and a connection region attached to the at least one first external contact element, wherein the plate region extends laterally beyond the edges of at least two sides of the second surface of the semiconductor chip.

### BACKGROUND

The present invention relates to a semiconductor device and a method of manufacturing the semiconductor device.

In the wake of a continuously increasing level of function integration in semiconductor devices, the number of input/output channels of semiconductor devices is rising continuously. At the same time, there is a rising demand for semiconductor devices that can switch large currents and voltages. A further driving force in the field of semiconductor manufacturing is to reduce costs. For those and other reasons, there is an ongoing effort to improve semiconductor devices and methods of manufacturing semiconductor devices.

### SUMMARY

Accordingly, there is provided a semiconductor device comprising: a carrier comprising a chip island and at least one first external contact element; only one semiconductor chip, wherein the semiconductor chip comprises a first electrode on a first surface and a second electrode on a second surface opposite to the first surface and wherein the first electrode is attached to the chip island; and a metal structure comprising a plate region attached to the second electrode and a connection region attached to the at least one first external contact element, wherein the plate region extends laterally beyond the edges of at least two sides of the second surface of the semiconductor chip.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Further, like reference numerals designate corresponding similar parts. Further, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

As employed in this Specification, the terms “coupled” and/or “electrically coupled” are not meant to mean that the elements must be directly coupled together; intervening elements may be provided between the “coupled” or “electrically coupled” elements.

FIGS. 1A and 1B schematically disclose two cross sections of an embodiment comprising a chip island, a chip soldered to chip island, an external contact element, and a metal structure soldered to chip and external contact element.

FIG. 1C schematically discloses a cross section of an embodiment wherein the plate region comprises a recess in the surface facing the semiconductor chip.

FIGS. 2A and 2B schematically disclose an embodiment wherein the semiconductor chip comprises multiple external contact elements and a connection element connecting the chip with a second external contact element.

FIGS. 3A and 3B schematically disclose an embodiment wherein mould material is used to cover the carrier, the chip and a part of the metal structure.

FIGS. 4A to 4E discloses a sequence for manufacturing a semiconductor device.

### DETAILED DESCRIPTION

Although specific embodiments have been illustrated and described herein, it will be appreciated by those of ordinary skill in the art that a variety of alternate and/or equivalent implementations may be substituted for the specific embodiments shown and described without departing from the scope of the present invention. For example, while the figures mainly refer to semiconductor devices having leadframes for non-leaded devices, the present invention may also apply to semiconductor devices having leadframes for leaded devices. Generally, this application is intended to cover any adaptations or variations of the specific embodiments discussed herein. Therefore, it is intended that this invention be limited only by the claims and the equivalents thereof.

Embodiments disclose a semiconductor device comprising a carrier comprising a chip island and at least one first external contact element. The chip island may be used for attaching a semiconductor chip to the carrier. The external contact elements may be leads or leadless contact elements that are used for contacting the semiconductor device to a printed circuit board. For example, the carrier may be a leadframe comprising a chip island and leads for soldering the semiconductor device to a printed circuit board.

The semiconductor device further comprises only one semiconductor chip. The only one semiconductor chip comprises a first electrode on a first surface and a second electrode on a second surface opposite to the first surface. Further, the first electrode of semiconductor chip is soldered to the chip island. Semiconductor devices with a first electrode on a first surface and a second electrode on the opposite second surface may comprise, for example, a power diode, a power transistor, an Insulated Gate Bipolar Transistor (IGBT), a Shottky diode, a Junction Field Effect Transistor (JFET), a Bipolar Junction Transistor (BJT), a Double Diffused MOS-Transistor (DMOS-Transistor), or a combination of those transistors or diodes. For example, semiconductor devices with a first electrode on one side and a second electrode on the respective other side may be power transistors that switch currents going from the first surface to the second surface of the semiconductor chip (i.e. “vertical transistor”), or vice versa. Power transistors are transistors that may switch currents as small as 100 mA, or as large as 1 A, 10 A, 100 A, 1000 A or even larger. In addition, power transistors may be able to switch voltages of more than, say, 24 V, up to 600 V, up to 10,000 V, or larger.

Embodiments further comprise a metal structure comprising a plate region soldered to the second electrode and an connection region soldered to the at least one first external contact element. Plate region may refer to a part of the metal structure that has a flat surface adapted to connect to a chip surface. Plate region and connection region may be made of one piece, e.g., of a metal foil or metal plate. The plate region extends laterally beyond the edges of at least two sides of the second surface of the semiconductor chip. With the plate region laterally extending beyond the edges, heat dissipation of heat generated by the semiconductor chip may increase significantly. With better heat dissipation, the semiconductor chip is able to switch higher currents or voltages without becoming destroyed by overheating. In this case, the metal structure serves both as a electrical connection connecting the second electrode with the at least one first external contact element, and as efficient heat dissipation means for heat generated in the semiconductor chip. The following figures will illustrate this in more detail by example.

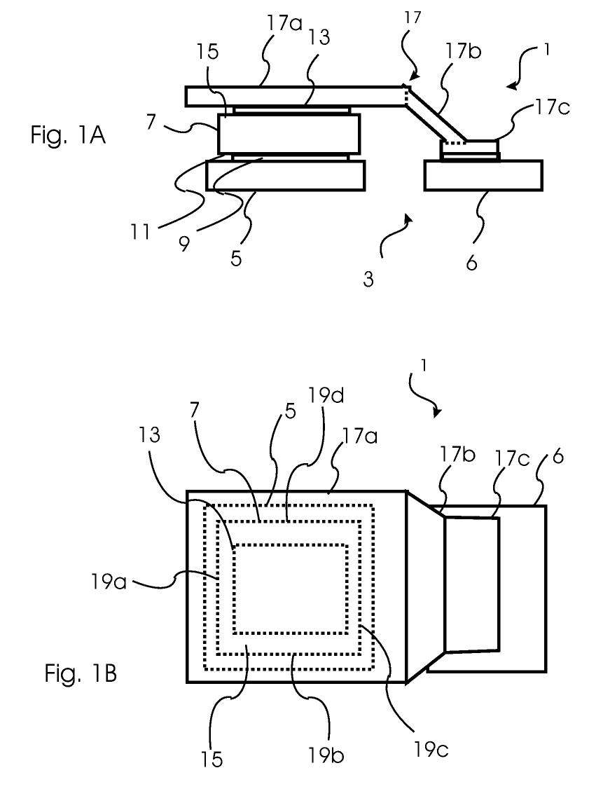

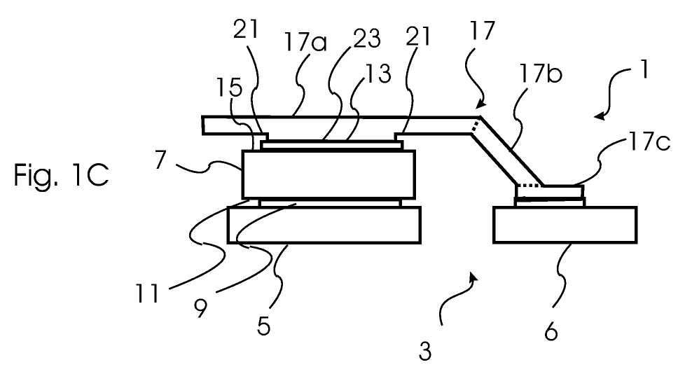

FIGS. 1A and 1B disclose schematically a cross section (FIG. 1A) and a top view (FIG. 1B) of a semiconductor device 1 comprising a leadframe 3 (carrier) consisting of a chip island 5 and an external contact element 6. Semiconductor device 1 further comprises a single semiconductor chip 7 having a first electrode 9 on a first surface 11 of the chip, and a second electrode 13 on the second surface 15 of the chip. Semiconductor chip 7 is attached to leadframe 3 by soldering first electrode 9 to chip island 5. The solder connection generally provides a small resistance between first electrode 9 and chip island 5. Soldering of chip 7 to chip island 5 may be carried out in one of the various known ways, e.g. soft soldering, hard soldering, or diffusion soldering, depending on the application and requirements. Alternatively, chip 7 may be attached to chip island 5 by means of paste soldering, electrically conducting glue attach, sintering, etc.

FIGS. 1A and 1B further disclose a clip 17 (metal structure) comprising a plate region 17a that is soldered to second electrode 13 of semiconductor chip 7. Clip 15 further comprises a connection region 17b, 17c that is soldered to external contact element 6. In one embodyment, plate region 17a and connection region 17b, 17c are part of an integral structure made of a metal, e.g. copper or a copper alloy. In the embodiment shown in FIGS. 1A and 1B, clip 17 may be formed of a copper strap that is bended two times in respective opposite directions along two parallel lines. As a result, clip 17 is comprised of plate region 17a, a bended region 17b, and a solder region 17c. Solder region 17c refers to the region of clip 17 that is soldered to external contact element 6. Note that the outlines of second electrode 13, semiconductor chip 7 and chip island 5 are drawn as dotted lines since, when seen from above, they are fully covered by plate region 17a.

In one embodiment, semiconductor chip 7 is a diode having two electrodes on opposite surfaces of the chip. With the diode having a first electrode 9 on one side and a second electrode 13 on the opposite side, the diode can be operated for rectifying a current across external voltages by connecting chip island 5 and external contact element 6 to respective external voltages.

The use of a clip for metal structure 15 has several advantages over other connection means. For example, it provides a large effective cross section for carrying large currents from chip 7 to external contact element 6 at a low resistance; it provides a superior design flexibility since a given clip, due to the solder interface between clip and external contact element, can be used for a variety of different leadframe and chip designs; and it provides for a superior rigidity that can withstand forces caused, for example, by liquid mould material rushing in during a molding process.

FIG. 1B further discloses that plate region 17a extends laterally beyond the edges of the four sides 19a, 19b, 19c, 19d of second surface 15 of semiconductor chip 7. This way, with the area of plate region 17a larger than the area of semiconductor chip 7, heat generated in semiconductor chip 7 during operation can be efficiently dissipated. The efficient heat dissipation is due to a superior heat conductance of the clip material in comparison to the mould material, due to the large heat capacitance provided by a larger plate region volume, due to the large surface of plate region 17 as a potential interface to the outside world, and due to the good thermal contact between chip 7 and plate region 17a.

Having plate region 17a extending latterally beyond the edges of semiconductor chip 7 has been avoided so far since the extension may provoke a short between the plate region 17a and the edges of semiconductor chip 7. This is because the second electrode, during operation, usually is at a different voltage than the edges of semiconductor chip 7.

Also, the use of a plate region 17a extending laterally beyond the edges of the four sides of second surface 15 of semiconductor chip 7 does not comply with present single chip leadframe packaging standards that use clips for contacting one of the electrodes, like the SS-08™ package by Infineon Technologies, the PowerPAK™ package by Vishay Intertechnology, Inc., etc. Those standard leadframe packages foresee clips that have plate regions extending only above the second electrode to avoid shorts and keep the size of the semiconductor device small.

FIG. 1c discloses schematically a cross section of an embodiment wherein a plate region 17a comprises a recess 21 in the surface facing the semiconductor chip 7. Recess 21 extends laterally beyond the edges of the at least two sides of the semiconductor chip. With the recess, a protruding region 23 on the plate region surface facing the semiconductor chip 7 is created that interfaces with second electrode 13. Recess 21 is to increase the distance between chip 7 and plate region 17a in the chip region outside of second electrode 13. The increased distance may prevent electric shorts that arise once the voltage between the electric potential of the chip substrate and the electric potential of plate region 17a rises beyond a given value during operation. In one embodiment recess 21 is imparted in all regions of plate region 17a that face chip 7 outside second electrode 13. The recess depth into the surface of plate region 17a is typically in a range of 100 to 1000 micrometers.

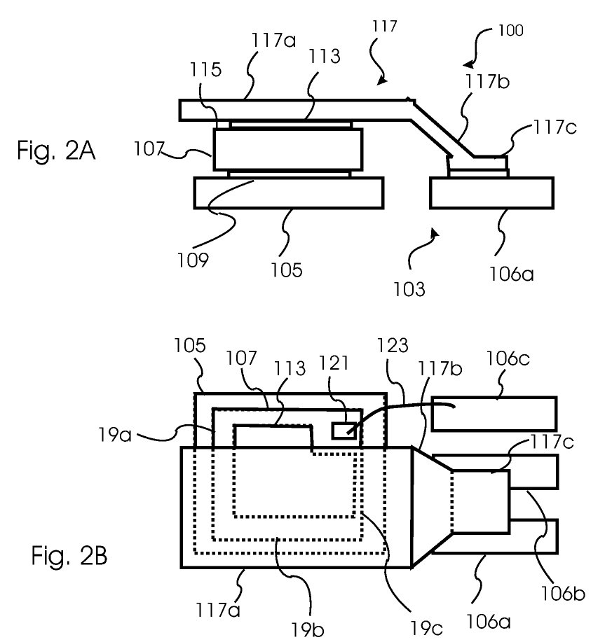

FIGS. 2A and 2B disclose a cross section (FIG. 2A) and a top view (FIG. 2B) of an embodiment that in many ways is similar to the embodiment of FIGS. 1A and 1B. Note that the top view of FIG. 2B shows those regions of second electrode 113, semiconductor chip 107 and chip island 105 as dotted lines that are covered by clip 117 (metal structure).

FIGS. 2A and 2B discloses a semiconductor device 100 comprising a semiconductor chip 107 that in addition to second electrode 113 has a third electrode 121 on second surface 115. In this embodiment, third electrode 121 is electrically connected to a second external contact element 106c via a bond wire 123 (connection element) while second electrode 113 is electrically connected to two first external contact elements 106a, 106b via clip 117 (metal structure). Third electrode 121 is located on the second surface 115 of semiconductor chip 107. Third electrode 121 may be the gate of a power transistor that controls a current flowing between first electrode 109 and second electrode 113 (“vertical transistor”), e.g. an insulated gate bipolar transistor (IGBT), or any of the transistors mentioned above. The area of third electrode 121 may be smaller than the area of first electrode by one or more orders of magnitude. Since the current through the gate is usually small or neglegible, the small cross section of a bond wire and the small electrode size does not present a significant limitation to the semiconductor device.

The embodiment of FIGS. 2A and 2B further discloses a leadframe 103 that, in addition to chip island 105, comprises three external contact elements 106a, 106b, 106c. Clip 117 is soldered to two of the three external contact element 106a, 106b, and to second electrode 113 to enable a low resistance connection between second electrode 113 and the two external contact elements 106a, 106b.

Clip 117 is comprised of a plate region 117a that is soldered to second electrode 113, a bended region 117b, and a solder region 117c that is coplanar to external contact element 6 and soldered to the external contact elements 106a, 106b. Further, plate region 117a extends beyond the edges of three sides 119a, 119b, 119c of second surface 115 of semiconductor chip 107. This is to obtain a superior heat dissipation for the heat generated in the semiconductor chip 107 during chip operation.

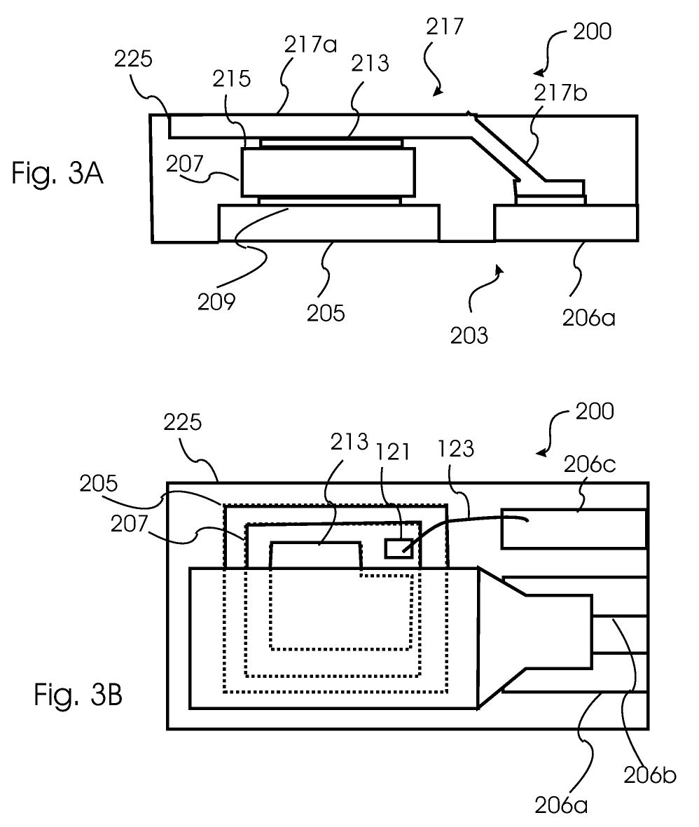

FIGS. 3A and 3B disclose a cross section (FIG. 3A) and a top view (FIG. 3B) of an embodiment. Leadframe 203, semiconductor chip 207 and clip 217 of semiconductor device 200 may, or may not, be the same as in FIGS. 2A and 2B. FIGS. 3A and 3B disclose mould material 225 covering the at least one first external contact element 206a, chip island 205, semiconductor chip 207 and a region of clip 217. Mould material 225 only partially covers clip 217 such that plate region 217a of clip 217 is exposed to the outside of the semiconductor device. This way, heat generated in semiconductor chip 307 can be efficiently dissipated to the environment through leadframe 213 as well as into the opposite direction through clip 217.

In one embodiment, the exposed region of plate region 217a is larger than the second the semiconductor chip, or even larger than chip island 205. In this case, heat generated in chip 217 and dissipated through clip 217 can flow in directions vertical and lateral with respect to the chip surface. In one embodiment, plate region 217a of clip 217 can be as thick or thicker than the semiconductor chip. For example, while the semiconductor chip 307 may have a thickness between 20 to 200 micrometers, the thickness of plate region 217a may be as large as 200 micrometers or larger. A thick plate region 17a improves heat dissipation in particular for pulsed currents with high energy densities.

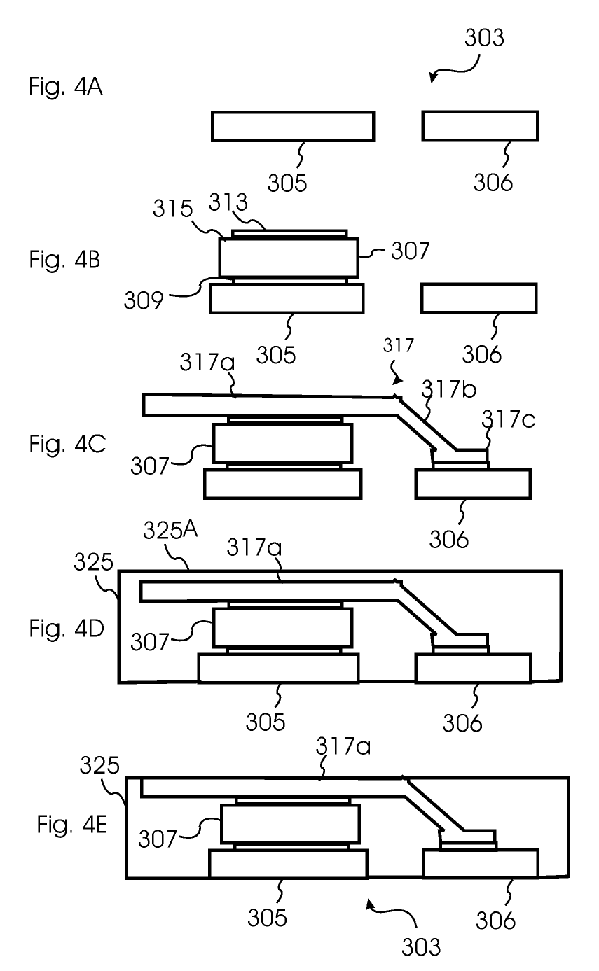

FIGS. 4A to 4E disclose an embodiment for manufacturing a semiconductor device. The method may be used, for example, for manufacturing one of the semiconductor devices described in the previous figures. FIG. 4A schematically discloses a leadframe 303 comprising a chip island 305 and multiple external contact element 306. The leadframe 303 shown in FIG. 4A is usually part of a leadframe strip (not shown) that contains a row or a matrix of leadframes integrally connected to each other via a leadframe strip structure. This way, as is well known in the art, chip island 305 and the first external contact elements 306a are held and kept in position to each other during the manufacturing process. It is usually only after moulding that the leadframe 303 is separated from the leadframe strip structure. The separation also separates chip island 305 from the external contact element 306. At this stage, a mould material body is formed that covers chip island 305, the chip 307, and external contact elements 306a and holds them together in one piece.

The material of the leadframe is typically copper, or a copper alloy, but other metals may be used as well. Additional metal layers may be applied to the leadframe to improve soldering properties or adherence to the moulding material. The thickness of the leadframe may be chosen according to the applications. Typical leadframe thicknesses are in the range between 125 micrometers and 500 micrometers or more. The external contact elements 306a of the leadframe may be through-hole leads to solder the semiconductor device to the through-holes of, say, a printed circuit board, e.g. Through-Hole-Device (THD), or gull wings as used for Surface Mounting Devices (SMD). The external contact elements 306a may also be used as non-leaded contact elements as used, for example, for Very-Thin-Profile-Quad-Flat-Non-Leaded (VQFN) packages.

FIG. 4B discloses leadframe 303 of FIG. 4A after semiconductor chip 307 has been soldered to chip island 305. Chip 307 may be a vertical power transistor, or diode, that has at least one first electrode 309 on a first surface and second electrode 313 on an opposite second surface 315. Chip 307 may also be an integrated circuit having at least one vertical power transistori or diode. If chip 307 comprises a vertical power transistor, first electrode 309 is usually the drain electrode and second electrode 313 is the source electrode of the vertical power transistor. The soldering of semiconductor chip 307 to chip island 305 may be carried out by one of known techniques mentioned before.

FIG. 4C discloses leadframe 303 and chip 307 after a clip 317 (metal structure) has been soldered to second electrode 313 and external contact element 306. Like in the previous embodiments, clip 317 may be an integral metal structure comprising a plate region 317a, a bended region 317b, and a solder region 317c that is soldered to external contact element 306. In one embodiment, plate region 317a may comprise a recess (not shown) of, say, 200 micrometers in the region facing chip 307 outside of second electrode 313. This is to increase the distance between clip 317 and chip 307 in the region outside of second electrode 313. The increased distance may strengthen the device against electric shorts between chip substrate and clip 317. Also, if moulding material is used to cover the chip 307, the mould material may enter the region between clip 317 and chip 307 in the region outside of second electrode 313. The moulding material in this region further strengthens the electric strength between chip substrate and clip 317. Soldering of clip 317 to external contact element 306 and second electrode 313 may be carried out, for example, with lead-based solder.

As indicated in the figure, the area of plate region 317a is larger than the area of chip 307, and larger than the area of chip island 305. While such large plate region area may increase the overall size of the package, it helps to have the clip 17 act as electrical connection connecting the chip to the external contact element 306, and as a heat dissipation means. As high temperature is often limiting the operational range of power transistors, the heat dissipation means can help increasing the capability of handling large currents.

FIG. 4D discloses leadframe 303, chip 307 and clip 317 of FIG. 4C after having the three covered with mould material 325. Molding may be carried out by placing the leadframe with the attached chip and clip in a mould form and, after closing the mould cavity, injecting liquid mould material into the cavity. The mould material 325 may be, for example, a duroplast epoxy resin that is injected into the cavity at a temperature of about 180° C. and at a pressure of about 90 bar. After injection, the moulded semiconductor device is cured until the mould material is hardened.

FIG. 4D further indicates that after moulding, a thin layer of mould material may cover the plate region. The layer may be as thin as 10 to 1000 micrometers. The thin mould material layer 325a prevents the plate region to be exposed to the outside of the semiconductor device. At the same time, the thin mould material layer 325a may limit heat dissipation of heat generated in chip 307. Still, for some moulding processes, the thin mould material layer 325a may be unavoidable because of the difficulty of preventing moulding material to creep into the gap between upper mouding tool and upper side of the plate region 317a.

FIG. 4E discloses the semiconductor device of FIG. 4D after thin mould material layer 325a has been removed (deflashing). The removal of the thin mould material layer 325a may be carried out mechanically, for example, by grinding or by a buffing wheel that removes the flash at a precision of 1 micrometer. The deflashing with a flashing wheel can be integrated in a process that also removes copper oxide layers on the external contact elements 306 and chip island 305. Alternatively, or in addition, the deflashing can be carried out by chemical means, e.g. by an etching process.

What is claimed is:

1. A semiconductor device, comprising:
a carrier comprising a chip island and at least one first external contact element;
only one semiconductor chip, the semiconductor chip comprising a first electrode on a first surface and a second electrode on a second surface opposite to the first surface, the first electrode being attached to the chip island; and
a metal structure comprising a plate region attached to the second electrode and a connection region attached to the at least one first external contact element; wherein the plate region extends laterally beyond the edges of at least two sides of the second surface of the semiconductor chip.

2. The semiconductor device according to claim 1 wherein the first electrode is soldered to the chip island.

3. The semiconductor device according to claim 1 wherein at least one of the plate region is soldered to the second electrode and the integral connection region is soldered to the at least one first external contact element.

4. The semiconductor device according to claim 1 wherein:
the carrier comprises at least one second external contact element;
the semiconductor chip comprises a a third electrode; and
the semiconductor device comprises a connection element connecting the third electrode with the at least one second external contact element.

5. The semiconductor device according to claim 1 wherein the third electrode is located on the second surface of the semiconductor chip.

6. The semiconductor device according to claim 1 further comprising mould material partially covering the at least one first external contact element.

7. The semiconductor device according to claim 6 wherein at least a region of the plate region is exposed to the outside of the semiconductor device.

8. The semiconductor device according to claim 6 wherein at least a region of the chip island is exposed to the outside of the semiconductor device.

9. The semiconductor device according to claim 7 wherein the area of the exposed region of the plate region is larger than the area of the chip island.

10. The semiconductor device according to claim 1 wherein the plate region is thicker than the thickness of the semiconductor chip.

11. The semiconductor device according to claim 1 wherein the plate region is integral with the connection region.

12. The semiconductor device according to claim 1 wherein the plate region comprises a recess in the surface facing the semiconductor chip, the recess extending laterally beyond the edges of the at least two sides of the semiconductor chip.

13. A semiconductor chip comprising:
a carrier comprising a chip island and at least one first external contact element;
a semiconductor chip comprising a first electrode on a first surface and a second electrode on a second surface opposite to the first surface, the first electrode being soldered to the chip island;
a metal structure soldered to the at least one first external contact element, the metal structure comprising a plate region soldered to the second electrode;
wherein the plate region extends laterally beyond the edges of at least two sides of the second surface of the semiconductor chip and is exposed to the outside of the semiconductor device; and
mould material covering the at least one first external contact element.

14. A method of manufacturing a semiconductor device, comprising:
providing a carrier comprising a chip island and multiple external contact elements;
providing a chip having a chip area;
providing a metal structure comprising a plate region having a plate region area that is larger than the chip area;
soldering the chip to the chip island;
soldering the plate region to the chip; and
covering the carrier with mould material.

15. The method of manufacturing the semiconductor device according to claim 14 wherein the area of the plate region is larger than the area of the chip island.

16. The method of manufacturing the semiconductor device according to claim 14 further comprising removing the mould material from the plate region.

17. The method according to claim 14 wherein the removal of the mould material from the plate region is carried out by mechanical means.

18. The method according to claim 14 wherein the removal of the mould material from the plate region is carried out by chemical means.

19. A semiconductor device, comprising:
a carrier comprising a chip island and at least one first external contact element;
only one semiconductor chip, the semiconductor chip comprising a first electrode on a first surface and a second electrode on a second surface opposite to the first surface, the first electrode being attached to the chip island; and
a metal structure comprising a plate region attached to the second electrode, the plate region extending laterally beyond the edges of at least two sides of the second surface of the semiconductor chip,
wherein the plate region comprises a recess in the surface facing the semiconductor chip, the recess extending laterally beyond the edges of the at least two sides of the semiconductor chip.

20. The semiconductor device according to claim 19 wherein the metal structure comprises an integral connection region attached to the at least one first external contact element.
